(19) United States
(12) Patent Application Publication
(10) Pub. No.: US 2007/0227586 A1
(43) Pub. Date: Oct. 4, 2007

(54) Detection and ablation of localized shunting defects in photovoltaics

(75) Inventor: George H. Zapalac JR., Nevada City, CA (US)

Correspondence Address: LNG/KLA JOINT CUSTOMER;C/O LUEDEKA, NEELY & GRAHAM, P.C., P.O. BOX 1871, KNOXVILLE, TN, 37901, US

(73) Assignee: KLA-Tencor Technologies Corporation, Milpitas, CA (US)

(21) Appl. No.: 11/278,158

(22) Filed: Mar. 31, 2006

(51) Int. Cl. H01L 31/00

(52) U.S. Cl. 136/252

(57) ABSTRACT

Increasing the efficiency of a photovoltaic stack by locating a position of a relatively small region in the photovoltaic stack that shunts the photocurrent generated within a substantially larger region of the photovoltaic stack, and electrically isolating at least a portion of the photovoltaic stack in the position of the localized shunting defect, so as to substantially remove any shunting effect caused by the localized shunting defect.

### FIELD

This invention relates to the field of photovoltaic cells. More particularly, this invention relates to reducing anomalies that tend to reduce the efficiency of thin film photovoltaic cells.

### BACKGROUND

Commercial thin film photovoltaic cells are made from a stack of from about four to about thirteen layers that generally range from tens of nanometers to a few microns in thickness. These structures are amenable to all inspection techniques for thin films on substrates, such as spectroscopic ellipsometry to determine layer thickness, or wavelength dispersive x-ray microanalysis to determine layer thickness and layer composition.

There are currently three main types of commercially produced thin film photovoltaic cells: amorphous silicon, cadmium telluride (CdTe), and copper indium gallium diselenide (CIGS). Many new types are expected to be introduced commercially in the future as more complex structures are investigated to increase efficiencies. A CIGS cell, for example, is generally grown on a glass substrate and consists of a back molybdenum contact of about one micron in thickness, an active p layer of CIGS of about two microns in thickness, an active n layer of CdS of about thirty nanometers in thickness, a transparent conductive oxide layer such as ZnO of about one micron in thickness, and an anti-reflective coating of MgF₂ of about one hundred nanometers in thickness.

Laboratory measurements of thin film photovoltaic samples with small areas (less than about one square centimeter) have demonstrated efficiencies comparable to those from crystalline silicon (greater than about fifteen percent for both cadmium telluride and CIGS photovoltaic cells). However, large commercial thin film photovoltaic modules (on the order of about one square meter) have much lower efficiencies, typically about one-half to about two-thirds of the efficiencies obtainable from small samples.

Much of this drop in efficiency for cadmium telluride modules might be due to localized regions of the cell that are forward biased, and which have been called “weak microdiodes.” CIGS modules have a similar structure and are probably susceptible to the same defect. Thin film photovoltaic cells may be modeled as an array of diodes with an average open circuit voltage, Voc. A small area of the film, on the order of the grain size (microns in diameter), can occasionally have a relatively much lower Voc than neighboring regions. This relatively lower Voc region tends to be forward biased by the surrounding relatively higher Voc region, and thereby shunts photocurrent from the surrounding region to the backside contact, thus diverting the photocurrent from the overall load, thereby reducing the efficiency of the cell. This current—and hence the shunted area of the cell—can be significant, due at least in part to the exponential dependence of the current on the forward bias of the weak microdiode. This problem tends to be unique to thin film photovoltaics because the thin film thickness is similar to the crystal grain size of the material so that variations in Voc tend to not average out with the depth of the thin film material.

One model for the area shunted by a weak microdiode is given by A=π(dV)/ρj. The area A is given in terms of the sheet resistance rho, the photocurrent density j, and the difference dV between the open circuit voltage of the weak microdiode and the average open circuit voltage of the surrounding region. For example, in direct sunlight, a cell with an efficiency of about ten percent would yield a photocurrent density of about twenty milliamperes per centimeter squared. Using a typical transparent conductive oxide sheet resistance of about ten ohms/square, a weak microdiode open circuit voltage of about three-hundred millivolts, and an average open circuit voltage of six-hundred and fifty millivolts, the area shunted by the weak microdiode region is determined to be about 5.5 square centimeters. This represents about five-hundred and fifty milliwatts of incident sunlight. This amount of light is said to saturate the weak microdiode, so that the photocurrent from additional light is not shunted and instead goes through the load. Saturation is achieved when the average product of the shunted current and the resistance of the transparent conductive oxide is approximately equal to the difference in open circuit voltages, dV.

One method that has been employed to alleviate this problem for CdTe photovoltaic cells is to treat the module with an electrolytic solution containing mostly aniline. The module is treated before the final contact is applied. This method might improve the efficiency of CdTe cells from about two or three percent to eleven percent. During the treatment, it is believed that ions from the solution migrate to the surface and distribute to reduce variations in Voc on the surface of the material, thereby reducing the likelihood of forming weak microdiodes.

However, the aniline treatment might be inappropriate for substrate configuration photovoltaic cells, which are photovoltaic cells such as CIGS that are grown on a substrate starting with deposition of the back contact and ending with deposition of the transparent conductive oxide contact. In the case of substrate configuration cells, the aniline layer would be deposited on the surface exposed to sunlight before the transparent conductive oxide is applied. However aniline undergoes photodegradation in sunlight with a half life of about three and one-half hours. Even for superstrate cells, the desired long term reliability (preferably about thirty years) of the aniline layer in the field is not known.

What is needed, therefore, is a system that overcomes problems such as those described above, at least in part.

### SUMMARY

The above and other needs are met by a method for increasing an efficiency of a photovoltaic stack by locating a position of a localized shunting defect in the photovoltaic stack, and electrically isolating at least a portion of the photovoltaic stack in the position of the localized shunting defect, so as to decrease and preferably substantially remove any shunting effect caused by the localized shunting defect.

In this manner, localized shunting defects that shunt photocurrent are electrically isolated and effectually removed from the photovoltaic. Electrical isolation of the worst localized shunting defects may increase the efficiency of a photovoltaic panel from about twelve percent efficiency before the treatment to about fifteen percent efficiency after the treatment. This increase of about twenty-five percent in efficiency allows the manufacturer to sell about an additional thirty watts per one meter square panel.

The step of locating the position of the localized shunting defect may be accomplished, for example, by sensing photocurrent produced by either an optical beam induced current or an electron beam induced current. The step of isolating at least a portion of the photovoltaic stack in the position of the localized shunting defect is preferably accomplished by laser ablation. The steps may be accomplished by use of a beam source that selectively produces a relatively weaker beam to locate the position of the localized shunting defect and then also selectively produces a relatively stronger beam to electrically isolate at least a portion of the photovoltaic stack.

The localized shunting defect may be isolated electrically from the rest of the cell by scribing the transparent conductive oxide layer or the back contact layer with a ring or other closed shape that circumscribes the position of the localized shunting defect. In other embodiments, at least all of the back contact layer of the photovoltaic stack is electrically isolated in the position of the localized shunting defect, at least all of a photovoltaic layer of the photovoltaic stack is electrically isolated in the position of the localized shunting defect, or at least all of the transparent conductive oxide layer is electrically isolated in the position of the localized shunting defect.

Removing at least a portion of the photovoltaic stack in the position of the localized shunting defect may be accomplished by cold laser photochemical ablation or laser thermal ablation. Locating the position of the localized shunting defect in the photovoltaic stack is preferably accomplished by measuring changes in photocurrent produced by the photovoltaic stack as a beam is scanned across the photovoltaic stack. The step of locating the localized shunting defect may be simultaneously accomplished with at least one of spectroscopic ellipsometry and photoluminescence mapping to monitor manufacturing quality.

The step of locating the position of the localized shunting defect in the photovoltaic stack is preferably accomplished with a transparent conductive oxide in place on the photovoltaic stack. This step also preferably includes regulation of a voltage across a load of the photovoltaic stack to a value that is slightly above an open circuit voltage of the localized shunting defect in order to reduce the light required to saturate the localized shunting defect. This improves the spatial resolution of the localized shunting defect without increasing an intensity of a beam that is used to locate the localized shunting defect.

According to another aspect of the invention there is described an apparatus adapted to detect and electrically isolate current shunting caused by a localized shunting defect from an effective circuit of a photovoltaic stack. A first beam source produces a first beam for locating a position of a localized shunting defect in the photovoltaic stack. A second beam source produces a second beam for electrically isolating at least a portion of the photovoltaic stack in the position of the localized shunting defect, so as to substantially remove any shunting effect caused by the localized shunting defect.

In various embodiments of this aspect of the invention, the first beam source and the second beam source are one beam source that produces at least two beams having different characteristics. The first beam preferably locates the position of the localized shunting defect by inducing a current. In some embodiments a third beam source scribes the photovoltaic stack. The first beam source, the second beam source, and the third beam source may all be one beam source that produces at least two beams having different characteristics. The first beam may simultaneously accomplish at least one of spectroscopic ellipsometry and photoluminescence mapping to monitor the quality of the cell.

In one embodiment of the invention, the ablation is performed by the same laser that is used to scribe the photovoltaic cell to create series connections within the cell. A separate beam preferably locates the position of the localized shunting defect by inducing a photocurrent, and then relays the coordinates of the localized shunting defects to the tool used to scribe the cell. In some embodiments a third beam source scribes the photovoltaic stack. The first beam source, the second beam source, and the third beam source may all be one beam source that produces at least two beams having different characteristics. This beam may simultaneously accomplish at least one of spectroscopic ellipsometry and photoluminescence mapping to monitor the quality of the cell.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 depicts the detection of a localized shunting defect in a photovoltaic.

FIG. 2 depicts the cold laser ablation of a localized shunting defect in a substrate configuration photovoltaic.

FIG. 3 depicts the substrate configuration photovoltaic after the localized shunting defect has been ablated.

FIG. 4 depicts the thermal laser ablation of a localized shunting defect in a superstrate configuration photovoltaic.

FIG. 5 depicts the superstrate configuration photovoltaic after the localized shunting defect has been ablated.

FIG. 6 depicts a system for detecting and ablating localized shunting defects according to a preferred embodiment of the present invention.

### DETAILED DESCRIPTION

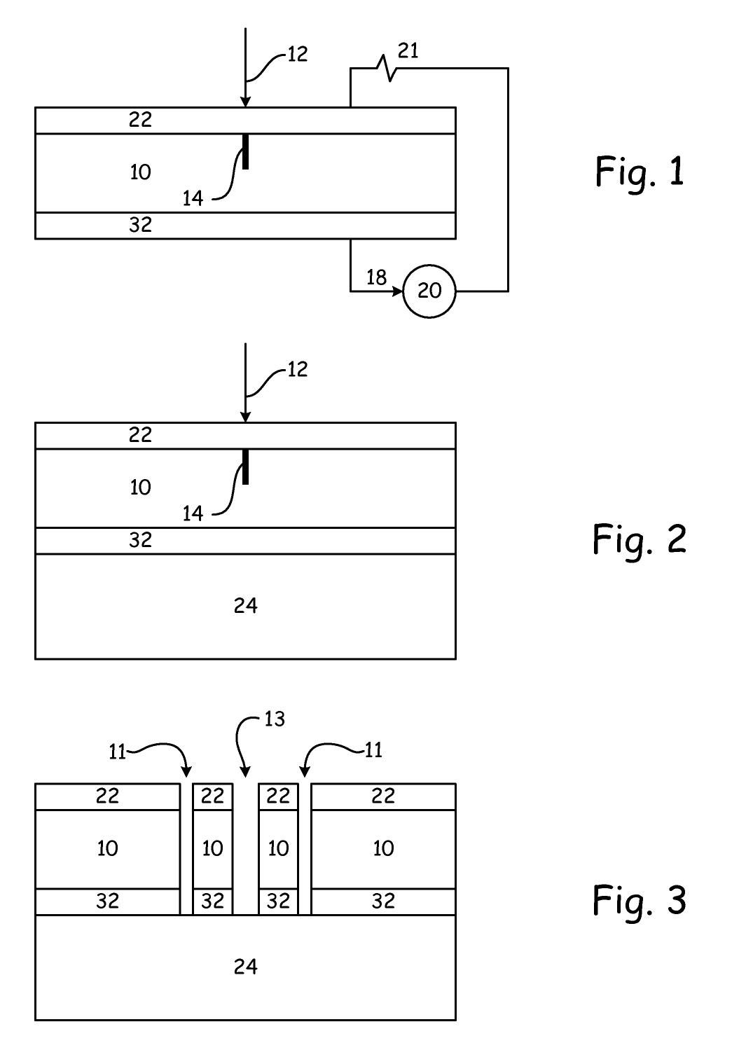

With reference now to FIG. 1, there is depicted a functional diagram for the detection of a localized shunting defect 14, such as the weak microdiode defect described above, in a photovoltaic 10. According to a preferred embodiment of the present invention, localized shunting defects 14 are preferably detected by measuring the photocurrent 18 from the cell 10 as a function of position. As depicted in FIG. 1, a light source 12 such as a laser or a lamp is focused to a spot on a portion of the cell 10. The photocurrent 18 from the light 12 is measured by an ammeter 20 in series with the load 21 resistance attached to the cell 10. The voltage across the load resistance 21 is preferably regulated to provide a constant bias on the cell 10, independent of the photocurrent 18 delivered to the load 21. Such a constant voltage is desirable to reduce and preferably eliminate changes in the forward bias of the localized shunting defect 14 when the photocurrent 18 changes with the beam 12 position.

Preferably, enough light 12 is provided by the source to saturate the localized shunting 14, so that the measured photocurrent 18 is always positive. For the example parameters of the photovoltaic cell described above, about five-hundred and fifty milliwatts of light at about the intensity of sunlight is preferably used to saturate the localized shunting defect 14 with an open circuit voltage of about three-hundred millivolts, if the cell 10 is biased to about six-hundred and fifty millivolts and the beam 12 is substantially centered on the localized shunting defect 14 with a spot diameter of about 2.6 centimeters.

Because the radius of the beam R˜sqrt(dV/j), the resolution increases with the intensity of the beam 12 and also increases with the reduction of the voltage difference dV between the open circuit voltage of the localized shunting defect 14 and the bias voltage across the load 21. For the present example, the area of the region suspected to contain the localized shunting defect 14 may be reduced by a factor of about twenty by increasing the optical power to about one and one-half watts and decreasing the bias voltage to about three-hundred and fifty millivolts. This procedure has the added advantage of turning off other nearby localized shunting defects in the cell 10 that happen to have higher open circuit voltages.

As the beam 12 spot moves away from the localized shunting defect 14, the resistance between the beam 12 and the localized shunting defect 14 due to the transparent conductive oxide 22 tends to increase, so that less photocurrent 18 is required to saturate the localized shunting defect 14, allowing the photocurrent 18 through the ammeter 20 to increase. In this manner the ammeter 20 measurement at constant bias allows the localized shunting defect 14 to be located.

Other methods may be used to locate the localized shunting defects 14. The inspection may be performed by electron beam induced current to locate the localized shunting defects 14. The inspection could also be performed by pyrometry under illumination to detect heating of the localized shunting defect 14 by the shunted photocurrent 18. The inspection could also be performed by a Kelvin probe to directly measure the open circuit voltage before either the transparent conductive oxide 22 or the back contact 32 is applied.

Once the localized shunting defect 14 is found, it is preferably electrically isolated by laser ablation, as depicted in FIGS. 2-3. As used herein, the phrase “electrically isolate” refers to one or more of a number of different methods by which the localized shunting defect 14 can be effectually “removed” from the larger electrical circuit. For example, electrical isolation can be accomplished by completely removing the material in which the localized shunting defect 14 is disposed. Electrical isolation can also be accomplished by removing material in the vicinity of the localized shunting defect 14, including material such as one or more of the transparent conductive oxide layer 22 and the back contact 32. Further, one or more of these materials may also be altered in some manner other than by removing them, which alteration causes one or more of the materials to no longer conduct an electrical current, which in turn would also electrically isolate the localized shunting defect 14.

Electrical isolation may also be accomplished by circumscribing the position of the localized shunting defect 14 in a manner that effectually “removes” the localized shunting defect 14 from the larger circuit. Again, this could be accomplished by either removing material around the position of the localized shunting defect 14 in some manner, or otherwise rendering it non electrically conductive in some manner, such as by impregnation of an atomic species in the material, for example. Thus, there are many different methods contemplated by which the localized shunting defect 14 can be electrically isolated. A few such methods are described in greater detail below.

For a substrate configuration, such as CIGS, that is typically manufactured beginning with the deposition of the back contact layer 32 as depicted in FIGS. 2-3, the photovoltaic material 10 containing the localized shunting defect 14 is preferably electrically isolated by scribing a ring 11 or other such closed shape through the transparent conductive oxide 22 to electrically isolate the region containing the localized shunting defect 14. The area enclosed by the ring scribe 11 is preferably significantly smaller than the area of the cell shunted by the localized shunting defect 14. Alternately, the localized shunting defect 14 itself is ablated, such as with the scribe 13. Preferably, one or the other, but not both, of the scribe 13 and the scribe 11 is used to electrically isolate the localized shunting defect 14. The photovoltaic material 10 and the back contact 32 may also be removed during this scribing process, but are not necessarily removed. The scribing process preferably removes the transparent conductive oxide 22 material using, for example, cold photochemical ablation with an ultra violet laser 12.

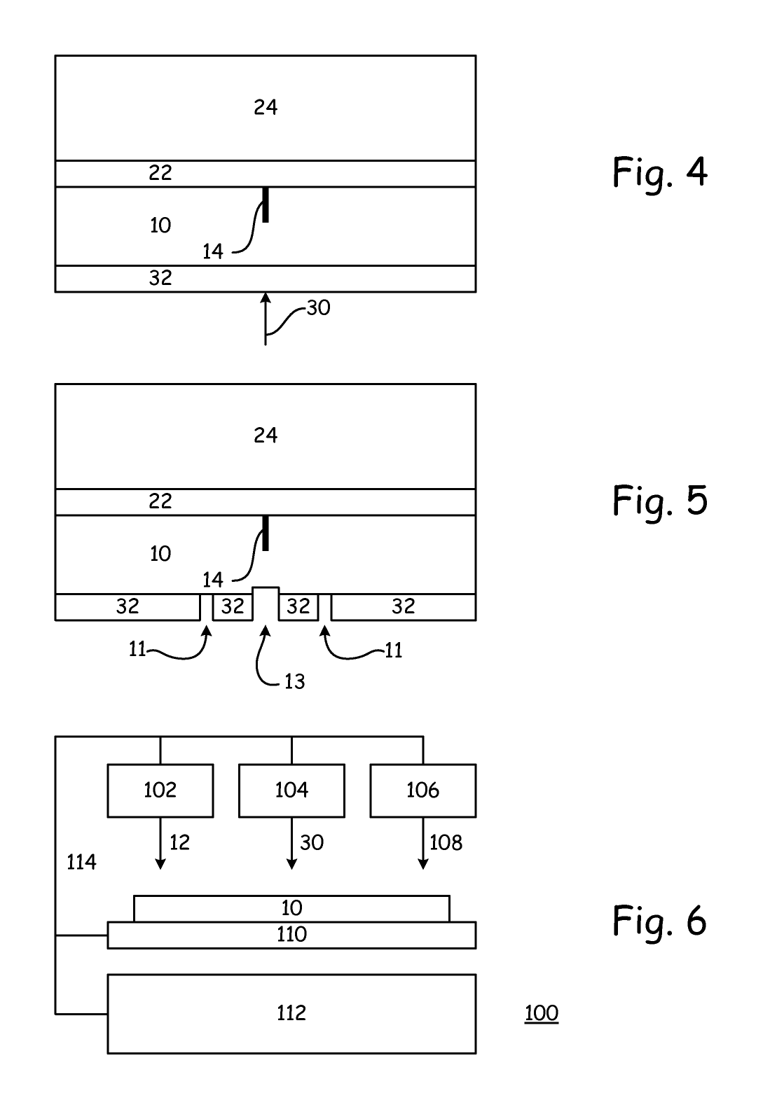

For a superstrate configuration such as CdTe that is typically manufactured beginning with the deposition of the transparent conductive oxide layer 22, as depicted in FIGS. 4-5, the localized shunting defect 14 is preferably electrically isolated by scribing a ring or other such closed shape through the back contact layer 32. Again, the scribing may also remove the back contact 32 in only the position of the localized shunting defect 14. The scribing may remove just the back contact layer 32, as depicted, or may additionally remove one or both of the photovoltaic material 10 and the transparent conductive oxide 22, in whole or in part.

In one embodiment, all of the photovoltaic material 10 is removed by ablation down to the substrate 24 in the position of the localized shunting defect 14. In yet another embodiment, all of the transparent conductive oxide 22 in the position of the localized shunting defect 14 is ablated in the substrate configuration (FIGS. 2-3), or all of the back contact 32 in the position of the localized shunting defect 14 is ablated in the superstrate configuration (FIGS. 4-5). In still another embodiment, all of the photovoltaic material 10 in the position of the localized shunting defect 14 is ablated down to the substrate 24. The ablation may be performed by means other than a laser, such as by using a focused ion beam (ion milling) or by a mechanical drill.

In some embodiments the laser or other beam source 12 is used for both inspection and ablation. In these embodiments the laser 12 is preferably either attenuated for the inspection phase, so as to not damage the cell 10, or is Q-switched for the ablation phase.

Data from the XY inspection of each cell module 10 may also be used as feedback to adjust settings for film 10 deposition during the manufacture of the module 10. It may be useful, for example, to use a polarized laser light 12 for the inspection and to simultaneously perform spectroscopic ellipsometry to monitor the thickness or average grain size in the film as a function of the XY position. Photoluminescence mapping to monitor minority carrier recombination is another diagnostic method that could be integrated into the laser inspection that is performed in the preferred embodiments of the invention.

During inspection, it may be effective to perform a rapid but coarse “pilot” inspection to map out regions of the panel 10 that have relatively lower efficiencies, such as an efficiency that is below a determined threshold, and are therefore likely to contain one or more localized shunting defects 14. The coarse or pilot mapping could be performed with a defocused beam 12 spot and higher regulated bias voltage across the load 21. The results from this mapping are preferably analyzed, as described above, for photoluminescence or spectroscopic ellipsometry to provide feedback for process control of the panel manufacture. Once the low efficiency regions of the panel are found, a finer inspection with a more focused beam 12 and reduced bias voltage is preferably performed on these regions to locate the more significant localized shunting defects 14 (such as about three-hundred millivolts to about three-hundred and fifty millivolts open circuit voltage) within a small enough area for laser 12 ablation to electrically isolate or remove the localized shunting defect 14.

For superstrate cells 10 (FIGS. 4-5), a separate laser 30 from the inspection laser 12 is preferably used for the ablation, because the photovoltaic material 10 is preferably ablated from the opposite side to avoid ablating the thick glass superstrate 24 that transmits the light to the cell 10 and acts as a substrate to support the cell 10. In one embodiment, laser 30 is preferably aligned with the inspection laser 12 during calibration of the tool that preferably performs both the inspection and the ablation.

For the case of photovoltaic cells 10 on very thin substrates, such as CIGS on twenty-five micron polyimide, it may be preferable in some embodiments to remove the substrate along with the photovoltaic material 10 and the back contact 32. In addition, it may be preferable in some embodiments to perform the ablation by the same laser that is used to scribe the panel to create series connections. Position coordinates for the localized shunting defects 14 from the inspection, for example, could be input to the scribing laser so that the localized shunting defects 14 are ablated by the same laser that performs the scribing.

Various embodiments of the present invention could be implemented, for example, in a commercial production line for thin film CIGS photovoltaic cells. Inspection would be performed by a focused two watt light source on a finished—but not yet scribed—panel 10 after deposition of the transparent conductive oxide contact film 22. Several hundred of the worst localized shunting defects 14 would be found on a one meter square panel. These localized shunting defects 14 would then be electrically isolated by laser ablation of the transparent conductive oxide layer 22 to scribe a circular ring enclosing the position determined from the inspection to contain the localized shunting defect 14. The ablation step could be integrated with laser scribing to create series connections between the photovoltaic cells 10 within a panel.

Removal of the worst localized shunting defects 14 could increase the efficiency of the panel 10 by twenty-five percent, from about twelve percent efficiency before the treatment to about fifteen percent efficiency after the treatment. An increase of about twenty-five percent in efficiency allows the manufacturer to sell about an additional thirty watts per one meter square panel, at an additional profit of about ninety dollars per panel, if the price of the photovoltaic is at about three dollars per watt. This amounts to a profit of over about one million dollars per year for the manufacturer, assuming half an hour to inspect and repair each panel and about twenty percent downtime for the tool.

FIG. 6 depicts a system 100 for implementing the methods described above according to a preferred embodiment of the present invention. The system 100 preferably includes a controller 112 that receives input from and sends control and other signals to the other components of the system 100, such as across communication lines 114. The work piece that includes the photovoltaic cell 10 is preferably disposed on a stage 110 of some type, which is operable to move the cell 10 relative to one or more beam sources 102, 104, and 106. Alternately, the cell 10 could remain stationary and the beam sources 102, 104, and 106 could be moved relative to the cell 10. Most preferably, the cell 10 is held or moved in such a manner that it is possible for the beams 12, 30, and 108 to strike the cell 10 from either side.

In the case of three beams, the beam usually used to scribe the cell would typically not be the same as the beam used to ablate the defects. The inspection/ablation/scribing or any combination thereof may occur on different stages. For example, beam 102 could inspect and then relate coordinates to fiducials on the solar cell, and then beam 104 could locate these same fiducials on a separate stage in the production line and then perform the ablations. All other combinations are also contemplated herein.

In one embodiment, the only beam source is beam source 102, which produces beam 12 that is configured to both inspect the cell 10 to find the localized shunting defect 14 as described above, and then ablate the localized shunting defect 14, in any one or more of the various manners described above. In further embodiments, the beam 12 can also be used to scribe the cell 10. However, in alternate embodiments, the beam source 102 is used to only produce a beam 12 that is operable to inspect the cell 10 and locate the localized shunting defects 14, and then a separate beam source 104 produces a beam 30 that is used to ablate the localized shunting defect 14, in any one or more the various manners described above. That beam 30 could also be used to scribe the cell 10. However, in yet another embodiment, the beam 30 is used only to ablate the localized shunting defect 14 and a third beam source 106 is used to produce a beam 108 that is operable to scribe the cell 10.

Most preferably, position information for the cell 10 is communicated from the various components to the controller 112, so that the location of localized shunting defects 14, and other position information as desired, can be recorded for the cell 10, and used during the various portions of the process as described. The position information can also be used for subsequent processes as desired, or used as feed back information to the processes by which the cell 10 is formed, so that they can be improved to produce fewer localized shunting defects 14.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A method for increasing an efficiency of a photovoltaic stack, the method comprising the steps of:
locating a position of a localized shunting defect in the photovoltaic stack, and
electrically isolating at least a portion of the photovoltaic stack in the position of the localized shunting defect, so as to decrease any shunting effect caused by the localized shunting defect.

2. The method of claim 1, wherein the step of locating the position of the localized shunting defect is accomplished by sensing at least one of an optical beam induced current and an electron beam induced current.

3. The method of claim 1, wherein the step of electrically isolating at least a portion of the photovoltaic stack in the position of the localized shunting defect is accomplished by removing at least a portion of the photovoltaic stack in the position of the localized shunting defect.

4. The method of claim 1, wherein the step of electrically isolating at least a portion of the photovoltaic stack in the position of the localized shunting defect is accomplished by laser ablation of at least one of the localized shunting defect, a transparent conductive oxide layer, a photovoltaic layer, and a back contact layer in the position of the localized shunting defect.

5. The method of claim 1, wherein the step of electrically isolating the localized shunting defect is accomplished by scribing an enclosed shape around the localized shunting defect, where at least one of a transparent conductive oxide layer, a photovoltaic layer, and a back contact layer is removed by the scribing.

6. The method of claim 1, wherein the steps of locating the position of the localized shunting defect and electrically isolating at least a portion of the photovoltaic stack in the position of the localized shunting defect are accomplished by use of a single beam source that selectively produces a relatively weaker beam to locate the position of the localized shunting defect and also selectively produces a relatively stronger beam to electrically isolate at least a portion of the photovoltaic stack.

7. The method of claim 1, wherein at least one of: (a) all of a back contact of the photovoltaic stack, (b) all of a photovoltaic layer of the photovoltaic stack, and (c) all of a transparent conductive oxide layer, is removed in the position of the localized shunting defect.

8. The method of claim 1, wherein at least one of: (a) all of a back contact of the photovoltaic stack, (b) all of a photovoltaic layer of the photovoltaic stack, and (c) all of a transparent conductive oxide layer, is removed in a circumscribed ring around the position of the localized shunting defect.

9. The method of claim 1, wherein at least one of: (a) at least some of a back contact of the photovoltaic stack, (b) at least some of a photovoltaic layer of the photovoltaic stack, and (c) at least some of a transparent conductive oxide layer, is removed in the position of the localized shunting defect.

10. The method of claim 1, wherein the step of electrically isolating at least a portion of the photovoltaic stack in the position of the localized shunting defect is accomplished by at least one of cold laser photochemical ablation and laser thermal ablation.

11. The method of claim 1, wherein the step of locating the position of the localized shunting defect in the photovoltaic stack is accomplished by measuring changes in a current produced by the photovoltaic stack as a beam is scanned across the photovoltaic stack.

12. The method of claim 1, wherein the step of locating the position of the localized shunting defect in the photovoltaic stack simultaneously accomplishes at least one of spectroscopic ellipsometry and photoluminescence mapping.

13. The method of claim 1, wherein the step of locating the position of the localized shunting defect in the photovoltaic stack is accomplished with a transparent conductive oxide in place on the photovoltaic stack, and includes regulation of a voltage across a load of the photovoltaic stack to a value that is slightly above an open circuit voltage of the localized shunting defect to improve spatial resolution of the localized shunting defect without increasing an intensity of a beam that is used to produce a saturation current from the localized shunting defect.

14. A method for increasing an efficiency of a photovoltaic stack, the method comprising the steps of:
locating a position of a localized shunting defect in the photovoltaic stack by measuring changes in a current produced by the photovoltaic stack as a beam is scanned across the photovoltaic stack, and
electrically isolating by laser ablation at least a portion of the photovoltaic stack in the position of the localized shunting defect so as to substantially remove any shunting effect caused by the localized shunting defect.

15. An apparatus adapted to detect and remove current shunting caused by a localized shunting defect from an effective circuit of a photovoltaic stack, the apparatus comprising:
a first beam source adapted to produce a first beam for locating a position of the localized shunting defect in the photovoltaic stack, and
a second beam source adapted to produce a second beam for electrically isolating at least a portion of the photovoltaic stack in the position of the localized shunting defect, so as to substantially remove any shunting effect caused by the localized shunting defect, wherein the first beam and the second beam have different characteristics.

16. The apparatus of claim 15, wherein the first beam source and the second beam source are one beam source adapted to produce at least two beams having different characteristics.

17. The apparatus of claim 15, wherein the first beam locates the position of the localized shunting defect by inducing a current.

18. The apparatus of claim 15, further comprising a third beam source adapted to produce a third beam for scribing the photovoltaic stack, wherein the first beam and the second beam have different characteristics.

19. The apparatus of claim 15, wherein the first beam source, the second beam source, and the third beam source are one beam source adapted to produce at least two beams having different characteristics.

20. The apparatus of claim 15, wherein the first beam is adapted to simultaneously accomplish at least one of spectroscopic ellipsometry and photoluminescence mapping.
